(19) United States
(12) Patent Application Publication
(10) Pub. No.: US 2025/0253796 A1
(43) Pub. Date: Aug. 7, 2025

(54) Switching Arrangement And Method For Detecting A Ground Connection

(71) Applicant: Schaeffler Technologies AG & Co. KG, Herzogenaurach (DE)

(72) Inventors: Dominik Will, Nürnberg (DE); Marc Arabackyj, Nürnberg (DE); Andreas Schnell, Kammerstein (DE); Robert Istvan Lorincz, Chisoda (RO)

(73) Assignee: Schaeffler Technologies AG & Co. KG, Herzogenaurach (DE)

(21) Appl. No.: 19/188,134

(22) Filed: Apr. 24, 2025

Related U.S. Application Data
(63) Continuation of application No. PCT/EP2023/079175, filed on Oct. 19, 2023.

(30) Foreign Application Priority Data
Oct. 24, 2022 (DE) 10 2022 211 265.2

(51) Int. Cl. H02P 29/024

(52) U.S. Cl. CPC H02P 29/027

(57) ABSTRACT

A switching arrangement with a B6 bridge for controlling an electric motor is provided. The lower semiconductor switches of each half bridge of the B6 bridge are connected to a motor ground via a common summing shunt. The switching arrangement includes a monitoring device for monitoring a current through the summing shunt based on a voltage that is dropped across the summing shunt. The monitoring device detects, in the event of a reverse current through the summing shunt that is higher than a predefined threshold value and lasts longer than a predefined period, a ground connection on the phase for which the semiconductor switches of the half bridge connected to this phase were last switched over such that the respective upper semiconductor switch is open and the respective lower semiconductor switch is closed. A method for detecting a ground connection of a phase of the electric motor is also provided.

### CROSS-REFERENCE TO RELATED APPLICATIONS

This application claims the benefit of PCT Application PCT/EP2023/079175, filed Oct. 19, 2023, which claims priority to German Application 10 2022 211 265.2, filed Oct. 24, 2022. The disclosures of the above applications are incorporated herein by reference.

### TECHNICAL FIELD

The disclosure relates to a switching arrangement for controlling an electric motor, and to a method for detecting a ground connection of a phase of an electric motor.

### BACKGROUND

It is known to monitor phase conductors of electric motors, for example brushless DC motors, or motor contacts to a control unit, for ground connections. It is furthermore known to monitor the drain-source voltage in a field-effect transistor of a driver circuit for electric motors. This monitoring depends greatly on a plurality of parameters, for example the type of the driver bridge circuit, the operating temperature thereof, the type of the short circuit (this must be very low-resistance) and the residual current through the motor. Furthermore, a temperature model for the affected components (for example FETs, IGBTs) must be implemented, this considerably increasing the effort for implementation and maintenance.

### SUMMARY

The disclosure provides an alternative solution for detecting ground connections of phase conductors of electric motors.

One aspect of the disclosure provides a switching arrangement including a B6 bridge for controlling an electric motor. The B6 bridge has three half bridges, each having an upper and a lower semiconductor switch between which a center tap is formed in each case, a respective phase of an electric motor is connected or able to be connected to the center tap. The upper semiconductor switch of each half bridge is connected or able to be connected to an operating voltage, where the lower semiconductor switch of each half bridge is connected or able to be connected to a motor ground. In some examples, the lower semiconductor switches of each half bridge are connected or able to be connected to the motor ground via a common summing shunt, where the switching arrangement further has a monitoring device for monitoring a current through the summing shunt on the basis of a voltage that is dropped across the summing shunt. The monitoring device is configured to detect, in the event of a reverse current through the summing shunt that is higher than a predefined threshold value and lasts longer than a predefined period, a ground connection on the phase for which the semiconductor switches of the half bridge connected to this phase were last switched over such that the respective upper semiconductor switch is open and the respective lower semiconductor switch is closed.

Implementations of the disclosure may include one or more of the following optional features. In some implementations, the defined period is longer than 5 μs.

In some examples, the semiconductor switches are in the form of transistors, such as field-effect transistors or IGBTs.

In some implementations, the monitoring device is configured to additionally carry out, for detecting ground connections, monitoring of the drain-source voltages of the semiconductor switches in the form of field-effect transistors or IGBTs.

In some examples, the monitoring device is configured to switch off the B6 bridge in the event of a ground connection being detected.

Another aspect of the disclosure provides a method for detecting a ground connection of a phase of an electric motor. The phases of which electric motor are connected to center taps of respective half bridges of a B6 bridge. The half bridges each have an upper and a lower semiconductor switch between which a center tap is formed in each case. The upper semiconductor switch of each half bridge is connected to an operating voltage, where the lower semiconductor switch of each half bridge is connected to a motor ground. In some examples, the lower semiconductor switches of each half bridge are connected to the motor ground via a common summing shunt, where a current through the summing shunt is monitored on the basis of a voltage that is dropped across the summing shunt. In the event of a reverse current through the summing shunt that is higher than a predefined threshold value and lasts longer than a predefined period, a ground connection is detected on the phase for which the semiconductor switches of the half bridge connected to this phase were last switched over, such that the respective upper semiconductor switch has been opened and the respective lower semiconductor switch has been closed.

In some examples, the defined period is longer than 5 μs.

In some implementations, in the event of a ground connection being detected and a high peak value of the reverse current occurring, a low-resistance ground connection and a low-resistance connecting resistance between the motor ground and a ground at which the ground connection of the phase exists is inferred. Whereas, in the event of a low peak value of the reverse current occurring, a high-resistance ground connection and a high-resistance connecting resistance between the motor ground and the ground at which the ground connection of the phase exists is inferred.

In some implementations, in the event of a ground connection and a rapid drop in the reverse current being detected, a low-inductance ground connection and a low connecting inductance between the motor ground and a ground at which the ground connection of the phase exists is inferred. Whereas in the event of a slow drop in the reverse current, a high-inductance ground connection and a high connecting inductance between the motor ground and the ground at which the ground connection of the phase exists is inferred.

In some implementations, the semiconductor switches are in the form of field-effect transistors or IGBTs, where, for detecting ground connections, monitoring of the drain-source voltages of the semiconductor switches is additionally carried out.

If a ground connection occurs, this then produces a reverse current through a summing shunt, which depends, on the one hand, on the type of the short circuit (that is to say its impedance) but, on the other hand, also on various other parameters. It is therefore possible for a driver A SIC or another technical solution, for example an analog circuit, to detect an overcurrent, which can be interpreted as a ground connection. After the overcurrent has been detected, the system reacts as follows: at least temporary deactivation of the B6 bridge driver, reporting the overcurrent; after the debouncing, the B6 bridge is permanently switched off, ground connection is detected; after a key cycle (resetting the control unit) the B6 bridge is put back into operation; and sporadic faults (short circuits) do not result in permanent unavailability of the control unit.

The disclosure provides the following advantages: lower effort for the implementation compared with monitoring the drain-source voltage, no temperature model required, no or little adaptation of the software required, no or less temperature dependency compared with monitoring the drain-source voltage, less maintenance effort over the product life cycle, in particular when design changes are performed (new sample phase, new driver components, in particular FETs or IGBTs), the detection of a broad spectrum of short circuits is possible, also higher-resistance short circuits than when monitoring the drain-source voltage, increased reliability of the product, increased detection rate of short circuits, in particular in combination with monitoring the drain-source voltage, and improved protection of the components (MOSFETs) is possible.

The disclosure may also be used for driver stages for electromagnetic valves or other electric loads, provided that a shunt is arranged accordingly.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a schematic circuit diagram of a B6 bridge having a summing shunt to motor ground,

FIG. 2 shows a schematic diagram of duty cycles of a pulse-width modulation at the B6 bridge,

FIG. 3 shows a schematic diagram of phase voltages and of a summing current,

FIG. 4 shows a schematic circuit diagram of the B6 bridge in the event of a ground connection of a phase, and

FIG. 5 shows a schematic circuit diagram of the B6 bridge after the semiconductor switches of the half bridge affected by the ground connection have been switched over.

Like reference symbols in the various drawings indicate like elements.

### DETAILED DESCRIPTION

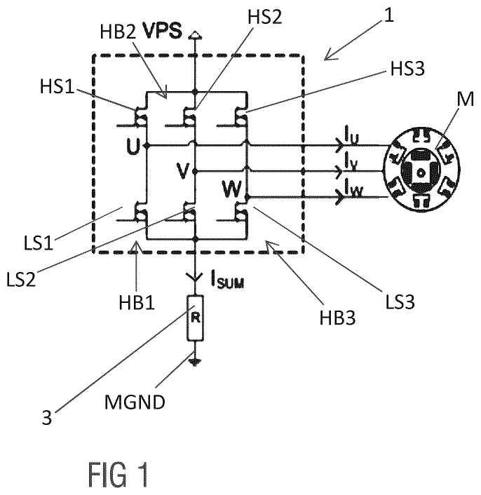

FIG. 1 is a schematic circuit diagram of a B6 bridge 1, including three half bridges HB1, HB2, HB3 each having two semiconductor switches HS1, LS1, HS2, LS2, HS3, LS3, for example transistors, such as field-effect transistors or IGBTs, between which a center tap is formed in each case. A respective phase U, V, W of an electric motor M, for example a brushless DC motor, is connected or able to be connected to the center tap. The upper semiconductor switches HS1 to HS3 of each half bridge HB1, HB2, HB3 are connected to an operating voltage VPS. The lower semiconductor switches LS1 to LS3 of each half bridge HB1, HB2, HB3 are connected to a motor ground MGND via a summing shunt 3. A current I_{SUM} through all of the lower semiconductor switches LS1 to LS3 therefore flows via the summing shunt 3 and can be ascertained, with knowledge of the resistance or the impedance of the summing shunt 3, by measuring a voltage that is dropped across the summing shunt.

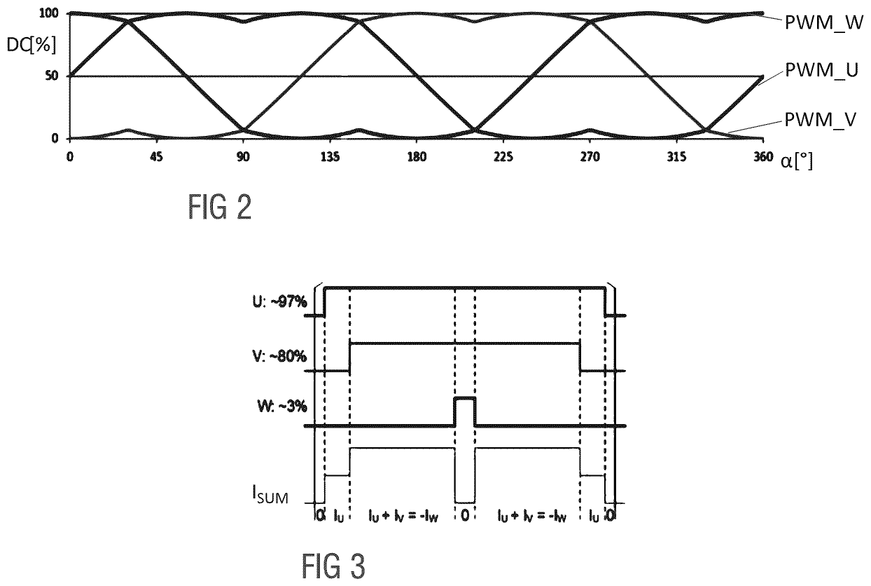

For example, the B6 bridge 1 is controlled, during normal operation, with a continuous sine wave modulation per pulse-width modulation. FIG. 2 is a schematic diagram of duty cycles DC of the pulse-width modulation as a function of a phase angle α. FIG. 3 is a schematic diagram of the phase voltages of the phases U, V, W and of the summing current I_{SUM}. The shown shape of the pulse-width modulation (in this example, it is produced “center aligned”, i.e. the high level is made wider starting from the center of the PWM period) is not essential for the functionality of the method.

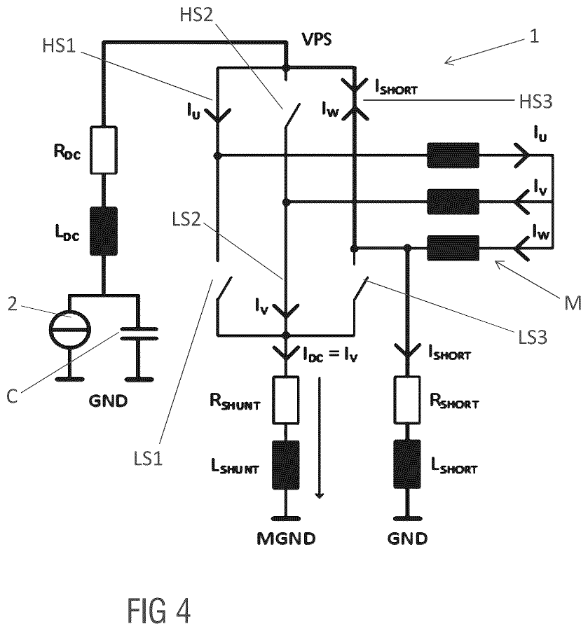

FIG. 4 is a schematic circuit diagram of the B6 bridge 1 in the event of a ground connection of the phase W. The summing shunt 3 is illustrated as a series connection including a shunt resistance R SHUNT and a shunt inductance L_{SHUNT}. The ground connection is illustrated as a series connection that includes a ground-connection resistance R_{SHORT} and a ground-connection inductance L_{SHORT}. A voltage source of the operating voltage VPS, for example a battery, is illustrated as a parallel connection of a current source 2 and of a capacitance C, for example a buffer capacitance of the B6 bridge 1, in series with a source resistance R_{DC} and a source inductance L_{DC}. In the illustrated situation, the semiconductor switches HS1, LS2 and HS3 are closed and the semiconductor switches LS1, HS2 and LS3 are open. A phase current I_{U} flows into the phase U of the electric motor M via the semiconductor switch HS1. A phase current I_{V} flows from the phase U of the electric motor M to motor ground MGND via the semiconductor switch LS2. A short-circuit current I_{SHORT} flows to ground GND via the semiconductor switch HS3. The ground GND may be a reference ground which may be formed, for example, by a metal base plate. The switching arrangement may be part of a control device, for example a gear control device for a motor vehicle, which may be arranged on the base plate. A voltage U SHUNT is dropped across the summing shunt 3, which voltage can be determined according to the following equation:

$${U}_{SHUNT} = {R}_{SHUNT} * {I}_{D C} ( + {L}_{SHUNT} * \frac{{dI}_{D C}}{d t} )$$

$${U}_{SHUNT} = {R}_{SHUNT} * {I}_{V} ( + {L}_{SHUNT} * \frac{{dI}_{D C}}{d t} )$$

where I_{DC} is the current flowing from the voltage source.

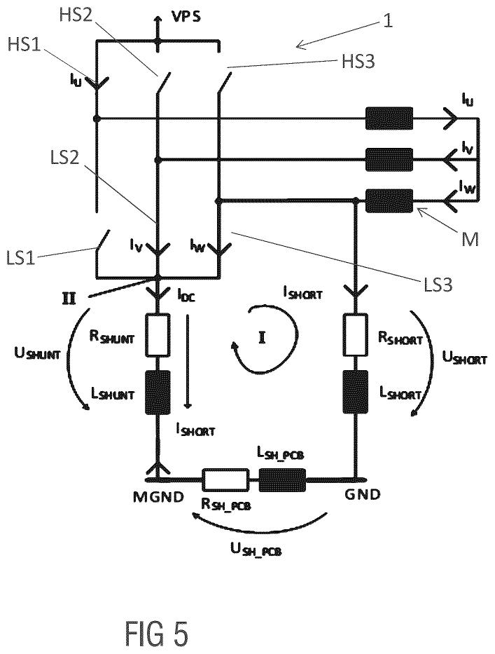

FIG. 5 is a schematic circuit diagram of the B6 bridge 1 after the semiconductor switches HS3, LS3 of the half bridge HB3 affected by the ground connection have been switched over, that is to say after the semiconductor switch HS3 has been opened and the semiconductor switch LS3 has been closed. A series connection that includes a connecting resistance R_{SH_PCB} and a connecting inductance L_{SH_PCB} is illustrated between ground GND and motor ground MGND (for example a connection between ground GND and motor ground M GND which can run, for example, partly via the metal base plate and partly via a printed circuit board). A discharge current flows from the phase conductor W partly via the ground connection and partly via the semiconductor LS3.

In this case, the following relationships apply:

$$I : {U}_{{SH}_{PCB}} + {U}_{SHORT} = {U}_{SHUNT}$$

$$II : {I}_{D C} = {I}_{U} - {I}_{SHORT}$$

$$II : {I}_{SHORT} = \int ( \frac{{U}_{L \_ SH \_ PCB}}{{L}_{SH \_ PCB}} ) * d t + c$$

$$IV : {U}_{SHUNT} = {R}_{SHUNT} * {I}_{D C} + {L}_{SHUNT} * \frac{{dI}_{D C}}{dt}$$

$${U}_{SHUNT} = {R}_{SHUNT} * ( {I}_{U} - \int ( \frac{{U}_{L \_ SH \_ PCB}}{{L}_{SH \_ PCB}} ) * d t + c ) + {L}_{SHUNT} * \frac{d ( {I}_{U} - \int ( \frac{{U}_{L \_ SH \_ PCB}}{{L}_{SH \_ PCB}} ) * d t + c )}{dt}$$

where: U_{SH_PCB} is the voltage that is dropped across the series connection includes the connecting resistance R_{SH_PCB} and the connecting inductance L_{SH_PCB}, U SHORT IS the voltage that is dropped across the series connection includes the ground-connection resistance R_{SHORT} and the ground-connection inductance L_{SHORT}, U_{L_SH_PCB} is the voltage that is dropped across the connecting inductance L_{SH_PCB}, and c is an initial current.

Based on the above theoretical considerations, the following assumptions are made:
The reverse current L_{SHUNT} flows through the summing shunt 3 as soon as the upper semiconductor switch HS3 is opened and the lower semiconductor LS3 is closed. The reverse current depends on the ground-connection resistance R_{SHORT}, on the ground-connection inductance L_{SHORT} and on the connecting inductance L_{SH_PCB} as has been shown above in the formulae. The reverse current I_{SHUNT} is always negative and thus flows from the motor ground MGND through the shunt 3 into the B6 bridge 1.
The ground-connection inductance L_{SHORT} and the connecting inductance L_{SH_PCB} act as current sources.
In the event of a low-resistance short circuit and a low-resistance connecting resistance R_{SH_PCB}, high peak values of the short-circuit current I_{SHORT} occur. In the event of a high-resistance short circuit and a high-resistance connecting resistance R_{SH_PCB}, low peak values of the short-circuit current I_{SHORT} Occur.
In the event of a low-inductance short circuit and a low connecting inductance L_{SH_PCB}, a rapid drop in the short-circuit current I_{SHORT} takes place. In the event of a high-inductance short circuit and a high connecting inductance L_{SH_PCB}, a slow drop in the short-circuit current I_{SHORT} takes place.
Since the brushless DC motor uses the absolute value of the current through the summing shunt 3, a negative current, provided that it is high enough, also triggers the OC mechanism and switches off the B6 bridge 1. The OC mechanism is configured to detect an overcurrent (OC) and may be in the form of an A SIC or part thereof.

The reverse current I_{SHUNT} can be ascertained by monitoring the voltage U_{SHUNT} that is dropped across the summing shunt 3 while taking account of the resistance or the impedance of the summing shunt 3.

A short circuit to ground GND is able to be detected, for example, if the voltage U_{SHUNT} across the summing shunt 3 is above a defined threshold value for a defined period, for example longer than 5 μs.

Tests have shown that the detection of ground connections can be drastically improved by the described detection of a reverse current I_{SHUNT}.

In some implementations, the detection of a ground connection by the described detection of a reverse current I_{SHUNT} is used in addition to monitoring the drain-source voltage.

A number of implementations have been described. Nevertheless, it will be understood that various modifications may be made without departing from the spirit and scope of the disclosure. Accordingly, other implementations are within the scope of the following claims.

### REFERENCE NUMERALS

1 B6 bridge
2 Current source
3 Summing shunt
C Capacitance
DC Duty cycle
GND Ground
HB1 to HB3 Half bridge
HS1 to HS3 Semiconductor switch, upper semiconductor switch
I_{DC} Current flowing from the voltage source
I_{SHORT} Short-circuit current
I_{SUM} Current
I_{U}, I_{V} Phase current
LS1 bis LS3 Semiconductor switch, lower semiconductor switch
L_{DC} Source inductance
L_{SHORT} Ground-connection inductance
L_{SHUNT} A shunt inductance
L_{SH_PCB} Connecting inductance
M Electric motor
MGND Motor ground
R_{DC} Source resistance
R_{SHORT} Ground-connection resistance
R_{SHUNT} Shunt resistance
R_{SH_PCB} Connecting resistance
U Phase
U_{L_SH_PCB} Voltage
U_{SHORT} Voltage
U_{SHUNT} Voltage
U_{SH_PCB} Voltage
V Phase
VPS Operating voltage
W Phase
α Phase angle

What is claimed is:

1. A switching arrangement, comprising:
a B6 bridge for controlling an electric motor, the B6 bridge has three half bridges each having an upper and a lower semiconductor switch between which a center tap is formed;
a respective phase of the electric motor is connected or able to be connected to the center tap, the upper semiconductor switch of each half bridge is connected or able to be connected to an operating voltage, the lower semiconductor switch of each half bridge is connected or able to be connected to a motor ground;
a common summing shunt connecting or being able to be connect the lower semiconductor switches of each half bridge to the motor ground; and
a monitoring device for monitoring a current through the summing shunt based on a voltage that is dropped across the summing shunt, the monitoring device detects, in the event of a reverse current through the summing shunt that is higher than a predefined threshold value and lasts longer than a predefined period, a ground connection on that phase for which the semiconductor switches of the half bridge connected to this phase were last switched over such that the respective upper semiconductor switch is open and the respective lower semiconductor switch is closed.

2. The switching arrangement of claim 1, wherein the defined period is longer than 5 μs.

3. The switching arrangement of claim 1, wherein the semiconductor switches are in the form of transistors.

4. The switching arrangement of claim 3, wherein the transistors include field-effect transistors or IGBTs.

5. The switching arrangement of claim 3, wherein the monitoring device, for detecting ground connections, monitors the drain-source voltages of the semiconductor switches in the form of field-effect transistors or IGBTs.

6. The switching arrangement of claim 1, wherein the monitoring device switches off the B6 bridge in the event of a ground connection being detected.

7. A method for detecting a ground connection of a phase of an electric motor, the phases of which are connected to center taps of respective half bridges of a B6 bridge, the half bridges each have an upper and a lower semiconductor switch between which a center tap is formed, wherein the upper semiconductor switch of each half bridge is connected to an operating voltage, the lower semiconductor switch of each half bridge is connected to a motor ground, the method comprising:
connecting the lower semiconductor switches of each half bridge to the motor ground via a common summing shunt;
monitoring a current through the summing shunt based on a voltage that is dropped across the summing shunt;
in the event of a reverse current through the summing shunt that is higher than a predefined threshold value and lasts longer than a predefined period, detecting a ground connection on the phase for which the semiconductor switches of the half bridge connected to this phase were last switched over such that the respective upper semiconductor switch has been opened and the respective lower semiconductor switch has been closed.

8. The method of claim 7, wherein the defined period is longer than 5 μs.

9. The method of claim 7, wherein:
in the event of a ground connection being detected and a high peak value of the reverse current occurring, inferring the existence of a low-resistance ground connection and a low-resistance connecting resistance between the motor ground and a ground at which the ground connection of the phase, and
in the event of a ground connection being detected and a low peak value of the reverse current occurring, inferring the existence of a high-resistance ground connection and a high-resistance connecting resistance between the motor ground and the ground at which the ground connection of the phase.

10. The method of claim 7, wherein:
in the event of a ground connection and a rapid drop in the reverse current being detected, inferring the existence of a low-inductance ground connection and a low connecting inductance between the motor ground and a ground at which the ground connection of the phase, and
in the event of a ground connection and a slow drop in the reverse current being detected, inferring the existence of a high-inductance ground connection and a high connecting inductance between the motor ground and the ground at which the ground connection of the phase.

11. The method of claim 7, wherein the semiconductor switches are in the form of field-effect transistors or IGBTs, wherein, for detecting ground connections, monitoring of the drain-source voltages of the semiconductor switches is additionally carried out.
